(19) United States
(12) Patent Application Publication
(10) Pub. No.: US 2015/0277136 A1
(43) Pub. Date: Oct. 1, 2015

(54) Laser Projection System with Potassium Gadolinium Tungstate

(71) Applicant: Laser Light Engines, Inc., Salem, NH (US)

(72) Inventors: Barret Lippey Lippey, Belmont, MA (US); Ian Lee, Chester, NH (US)

(73) Assignee: Laser Light Engines, Inc., Salem, NH (US)

(21) Appl. No.: 14/230,307

(22) Filed: Mar. 31, 2014

(51) Int. Cl. G02B 27/48; H01S 5/06; H01S 5/00; G03B 21/20; G02B 27/22

(52) U.S. Cl. CPC G02B 27/48; G03B 21/2033; G03B 21/2093; G02B 27/2228; H01S 5/0092; H01S 5/0604

(57) ABSTRACT

An apparatus and method for enhancing light using stimulated Raman scattering in a potassium gadolinium tungstate (KGW) crystal. The stimulated Raman scattering is utilized to add wavelength diversity for reduced speckle and to change the color of the light to a more desirable combination of wavelengths. Digital projection is one application that may benefit from lower speckle and shifted color. Color-based stereoscopic projection is enabled by the addition of stimulated Raman bands at specific wavelengths.

### BACKGROUND OF THE INVENTION

There are many advantages of using laser light sources to illuminate digital projection systems, but the high coherence of laser light tends to produce undesirable speckle in the viewed image. Known despeckling methods generally fall into the categories of polarization diversity, angle diversion, and wavelength diversity. In the laser projection industry, there has been a long-felt need for more effective despeckling methods.

### SUMMARY OF THE INVENTION

In general, in one aspect, an optical apparatus that includes a potassium gadolinium tungstate (KGW) crystal, a green laser, and a digital projector. The green laser illuminates the KGW crystal, a stimulated Raman scattering in the KGW crystal enhances an aspect of the light output from the KGW crystal, and the light output of the KGW crystal illuminates the digital projector.

Implementations may include one or more of the following features. The aspect of the light output from the KGW crystal may be speckle or color. The light output from the KGW crystal may include a band of green light and a band of red light. There may also be a multipass cell, and the green laser may illuminate the KGW crystal with multiple passes that are determined by the multipass cell. There may also be a KGW resonant cavity and the resonant optical condition for the KGW crystal may be determined by the KGW resonant cavity. The KGW crystal may be located inside the green laser resonant cavity. The light output from the digital projector may meet the Digital Cinema Initiative color requirements. The light output of the KGW crystal may be separated into two wavelength bands. The first wavelength band may be used to form the first-eye image of a stereoscopic image projected from the digital projector. The second wavelength band may be used to form the second-eye image of the stereoscopic image. The green laser may include a fiber laser.

In general, in one aspect, a method of despeckling that includes generating a green laser beam from a green laser, focusing the laser beam into a potassium KGW crystal, generating stimulated Raman scattering light in the KGW crystal, using the stimulated Raman scattering light to enhance an aspect of the light output from the KGW crystal, and using the light output of the KGW crystal to illuminate a digital projector.

Implementations may include one or more of the following features. The aspect of the light output from the KGW crystal may be speckle or color. The light output from the KGW crystal may include a band of green light and a band of red light. The green laser beam may illuminate the KGW crystal with multiple passes that are determined by a multipass cell. The green laser beam may illuminate the KGW crystal with a resonant optical condition that is determined by a KGW resonant cavity. The KGW crystal may be located inside the green laser resonant cavity. The light output from the digital projector may meet Digital Cinema Initiative color requirements. There may also be a step of separating the light output of the KGW crystal into a first wavelength band and a second wavelength band. The first wavelength band may be used to form the first-eye image of a stereoscopic image in the digital projector. There may also be a step of projecting the stereoscopic image from the digital projector. The green laser may include a fiber laser.

### BRIEF DESCRIPTION OF THE SEVERAL VIEWS OF THE DRAWING

FIG. 1 is a top view of laser projection system with a potassium gadolinium tungstate (KGW) crystal in a multipass cell;

FIG. 2 is a top view of a laser projection system with a KGW crystal in a KGW resonant cavity;

FIG. 3 is a top view of a laser projection system with a KGW crystal in a green laser resonant cavity;

FIG. 4 is a spectral graph of a a laser projection system with a KGW crystal in a multipass cell;

FIG. 5 is a color chart of a laser projection system with a KGW crystal in a multipass cell;

FIG. 6 is a spectral graph of a laser projection system with a KGW crystal in a resonant cavity;

FIG. 7 is a color chart of a laser projection system with a KGW crystal in a resonant cavity;

FIG. 8 is a spectral graph of a stereoscopic laser projection system with a KGW crystal in a multipass cell;

FIG. 9 is a color chart of a stereoscopic laser projection system with a KGW crystal in a multipass cell;

FIG. 10 is a computer-simulated time graph of stimulated Raman scattering in a KGW crystal;

FIG. 11 is a computer-simulated spectral graph of stimulated Raman scattering in a KGW crystal;

FIG. 12 is a flowchart of a method of laser projection with a KGW crystal; and

FIG. 13 is a flowchart of a method of stereoscopic laser projection with a KGW crystal.

### DETAILED DESCRIPTION

Conventional laser projection systems are typically constructed with narrow-band laser sources. The narrow bands of light tend to produce speckle patterns in the projected images. Spectral broadening of the laser sources may be used to add wavelength diversity that reduces the level of speckle. By using stimulated Raman scattering in a potassium gadolinium tungstate (KGW) crystal, additional Stokes-shifted peaks may be added to help reduce laser speckle with wavelength diversity. The Stokes-shifted peaks are individually broadened compared to the starting peaks, so the wavelength broadening effect is magnified when compared to adding additional narrow peaks. With appropriate balancing of wavelengths and amplitudes, Digital Cinema Initiative (DCI) color points can be achieved for red, green, and blue primary colors, along with the DCI white point.

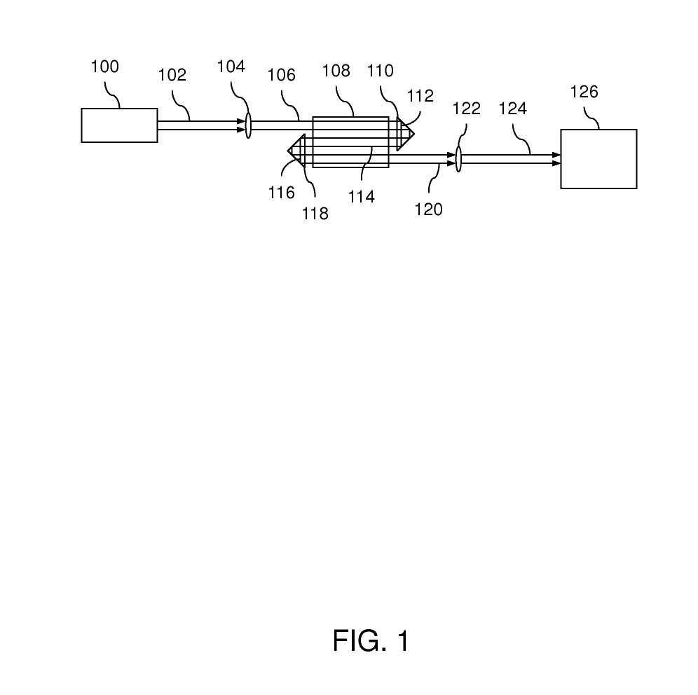

FIG. 1 shows a top view of a laser projection system with a potassium gadolinium tungstate (KGW) crystal in a multipass cell. Green laser 100 generates first light beam 102. First light beam 102 illuminates first lens assembly 104. First lens assembly 104 produces second light beam 106. Second light beam 106 illuminates KGW crystal 108 and generates SRS light that is shown as included in second light beam 106. Second light beam 106 is reflected by first reflector 110 to produce third light beam 112. Third light beam 112 is reflected by first reflector 110 to produce fourth light beam 114. Fourth light beam 114 illuminates KGW crystal 108 and generates SRS light that is shown as included in fourth light beam 114. Fourth light beam 114 is reflected by second reflector 118 to produce fifth light beam 118. Fifth light beam 118 is reflected by second reflector 118 to produce sixth light beam 120. Sixth light beam 120 illuminates KGW crystal 108 and generates SRS light that is shown as included in sixth light beam 120 and seventh light beam 124. Sixth light beam 120 illuminates second lens assembly 122. Second lens assembly 122 produces seventh light beam 124. Seventh light beam 124 illuminates digital projector 126. KGW crystal 108, first reflector 110, and second reflector 118, form a multipass cell. The number of passes through the KGW crystal may be modified to attain a longer or shorter path length as desired to convert more of less of the green laser light to SRS light. Three passes through the KGW crystal are shown in FIG. 1, but any number of passes may be utilized. The lens assemblies may be any combination of lens or other optical elements that are designed to collect and shape the beam for optimal effect in each part of the system. The reflectors may be corner cube prisms, flat mirrors, or other optical elements that reflect the beams appropriately. To construct a three-color projection system, red and blue lasers may be added, but are not shown in FIG. 1. Digital projector 126 may be a projector based on digital micromirror (DMD), liquid crystal device (LCD), liquid crystal on silicon (LCOS), or other digital light valves. Additional elements may be included to further guide or despeckle the light such as additional lenses, diffusers, vibrators, or optical fibers.

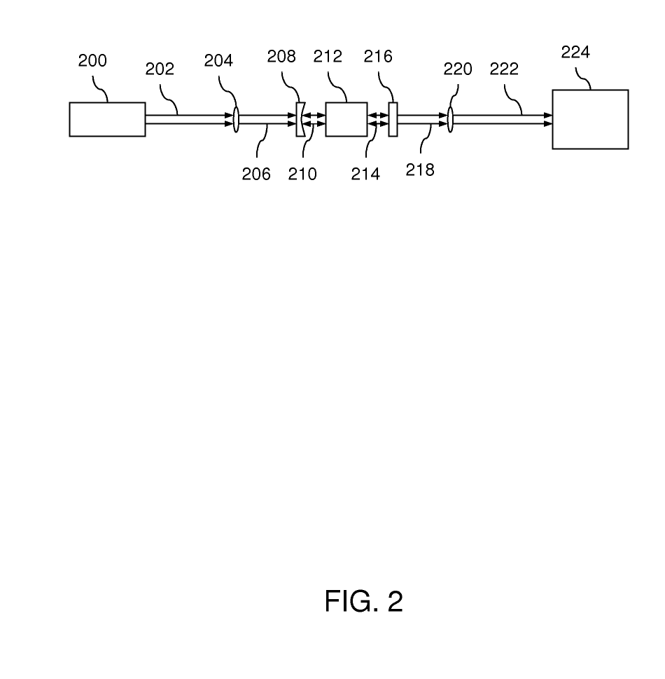

FIG. 2 shows a top view of a laser projection system with a KGW crystal in a KGW resonant cavity. Green laser 200 generates first light beam 202. First light beam 202 illuminates first lens assembly 204. First lens assembly 204 produces second light beam 206. Second light beam 206 illuminates first partial mirror 208. First partial mirror 208 produces third light beam 210. Third light beam 210 illuminates KGW crystal 212. KGW crystal 212 produces fourth light beam 214. Fourth light beam 214 illuminates second partial mirror 216. Second partial mirror 216 produces fifth light beam 218. Fifth light beam 218 illuminates second lens assembly 220. Second lens assembly 220 produces sixth light beam 222. Sixth light beam 222 illuminates digital projector 224. First partial mirror 208, KGW crystal 212, and second partial mirror 216 from a KGW resonant cavity such that light is reflected multiple times between first partial mirror 208 and second partial mirror 216. KGW crystal 212 generates SRS light that is shown as included in third light beam 210, fourth light beam 214, fifth light beam 218, and sixth light beam 222. First partial mirror 208 and second partial mirror 2167 have partial reflection designed to form a resonant cavity at desired wavelengths. First partial mirror 208 may be spherically shaped to help stabilize the beam in the resonant cavity. Partial mirrors may be constructed with dichroic coatings to transmit and reflect various wavelengths at desired levels and to convert the desired amount of the green laser light to SRS light. The lens assemblies may be any combination of lens or other optical elements that are designed to collect and shape the beam for optimal effect in each part of the system. To construct a three-color projection system, red and blue lasers may be added, but are not shown in FIG. 2. Digital projector 224 may be a projector based on digital micromirror (DMD), liquid crystal device (LCD), liquid crystal on silicon (LCOS), or other digital light valves. Additional elements may be included to further guide or despeckle the light such as additional lenses, diffusers, vibrators, or optical fibers.

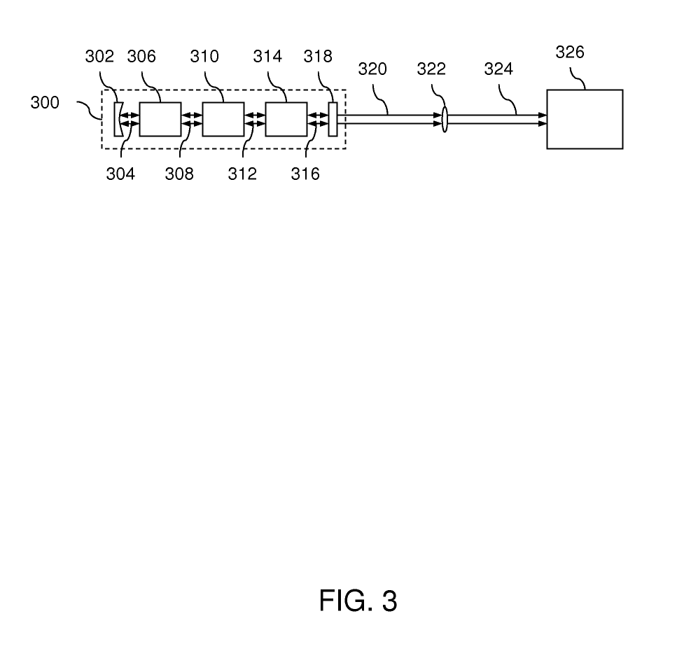

FIG. 3 shows a top view of a laser projection system with a KGW crystal in a green laser resonant cavity. Green laser 300 generates first light beam 320. First light beam 320 illuminates first lens assembly 322. First lens assembly 322 produces second light beam 324. Second light beam 206 illuminates digital projector 326. Green laser 300 includes mirror 302, lasing crystal 306, second harmonic generation (SHG) crystal 310, KGW crystal 314, and partial mirror 318. Mirror 302 and partial mirror 318 from a green laser resonant cavity at desired wavelengths such that light is reflected multiple times between mirror 302 and partial mirror 318. Third light beam 304 carries infrared (IR) light, unshifted green light, and SRS light between mirror 302 and lasing crystal 306. Fourth light beam 308 carries IR light, unshifted green light, and SRS light between lasing crystal 306 and SHG crystal 310. Fifth light beam 312 carries IR light, unshifted green light, and SRS light between SHG crystal 310 and KGW crystal 314. Sixth light beam 316 carries IR light, unshifted green light, and SRS light between KGW crystal 314 and partial mirror 318. Partial mirror 318 allows some light to pass through to generate first light beam 320. Lasing crystal 306 generates coherent IR light and may be constructed from neodymium-doped yttrium aluminum garnet (Nd:YAG), neodymium-doped yttrium vanadate (Nd:YVO₄), neodymium-doped yttrium lithium fluoride (Nd:YLF), or another lasing material. SHG crystal 310 converts some of the coherent IR light to unshifted green light and may be constructed from lithium triborate (LBO) or other nonlinear optical material. KGW crystal 314 converts some of the unshifted green light to SRS light. Mirror 302 may be spherically shaped to help stabilize the beam in the resonant cavity. Partial mirrors may be constructed with dichroic coatings to transmit and reflect various wavelengths at desired levels and to convert the desired amount of the unshifted green laser light to SRS light. The lens assembly may be any combination of lens or other optical elements that are designed to collect and shape the beam for optimal effect in the digital projector. To construct a three-color projection system, red and blue lasers may be added, but are not shown in FIG. 3. Digital projector 326 may be a projector based on digital micromirror (DMD), liquid crystal device (LCD), liquid crystal on silicon (LCOS), or other digital light valves. Additional elements may be included to further guide or despeckle the light such as additional lenses, diffusers, vibrators, or optical fibers.

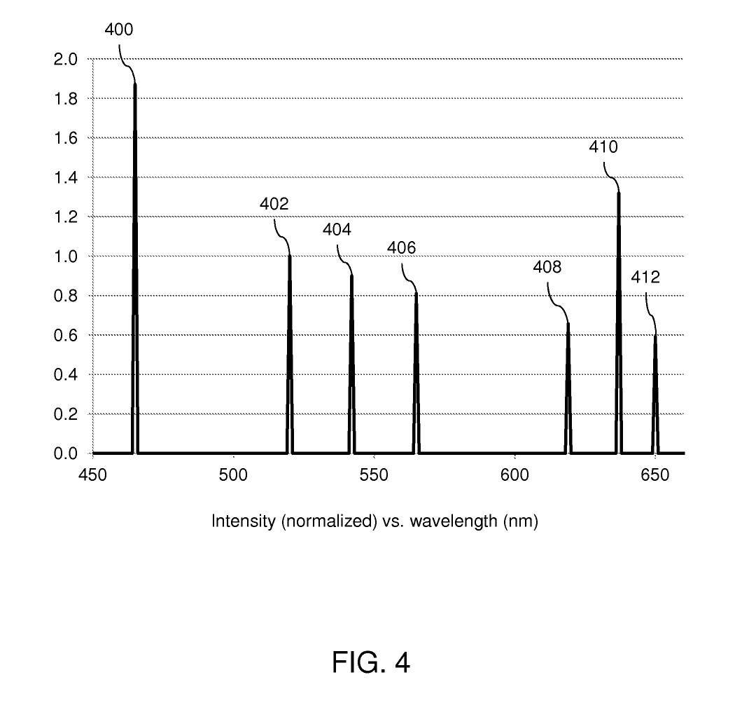

FIG. 4 shows a spectral graph of a laser projection system with a KGW crystal in a multipass cell. The horizontal axis represents wavelength in nanometers and the vertical axis represents normalized light intensity. First peak 400 is generated by blue laser diodes at 465 nm. Second peak 402, third peak 404, fourth peak 406, fifth peak 408, and seventh peak 412 correspond to the spectral output of the laser projection system shown in FIG. 1. Second peak 402 is formed from unshifted green light at 520 nm. Third peak 404, fourth peak 406, fifth peak 408, and seventh peak 412 are formed from SRS light at 542 nm, 565 nm, 619 nm, and 650 nm. Sixth peak 410 is generated by red laser diodes at 637 nm. Second peak 402, third peak 404, and fourth peak 406 represent a despeckled green primary color. Fifth peak 408, sixth peak 410, and seventh peak 412 represent a despeckled red primary color. An SRS peak at 591 nm is not shown because it is filtered out by low projector transmission between the green and red bands. The vertical axis is normalized to second peak 402. Although not shown to scale in FIG. 4, second peak 402 is typically a very narrow peak that has a width of much less than one nanometer, whereas the other peaks typically have bandwidths in the range of 1 to 5 nm each. Third peak 404, fourth peak 406, fifth peak 408, and seventh peak 412 are broadened by the SRS process. First peak 400 and sixth peak 410 are broadened by the properties of the laser diodes that are used to create those peaks. The amplitudes of third peak 404, fourth peak 406, fifth peak 408, and seventh peak 412 are determined by the KGW conversion parameters such as the beam diameter and length in the KGW crystal and the green laser peak power and pulse shape. The amplitudes of first peak 400, second peak 402, and sixth peak 410 are determined by the output powers of the blue, green, and red lasers respectively.

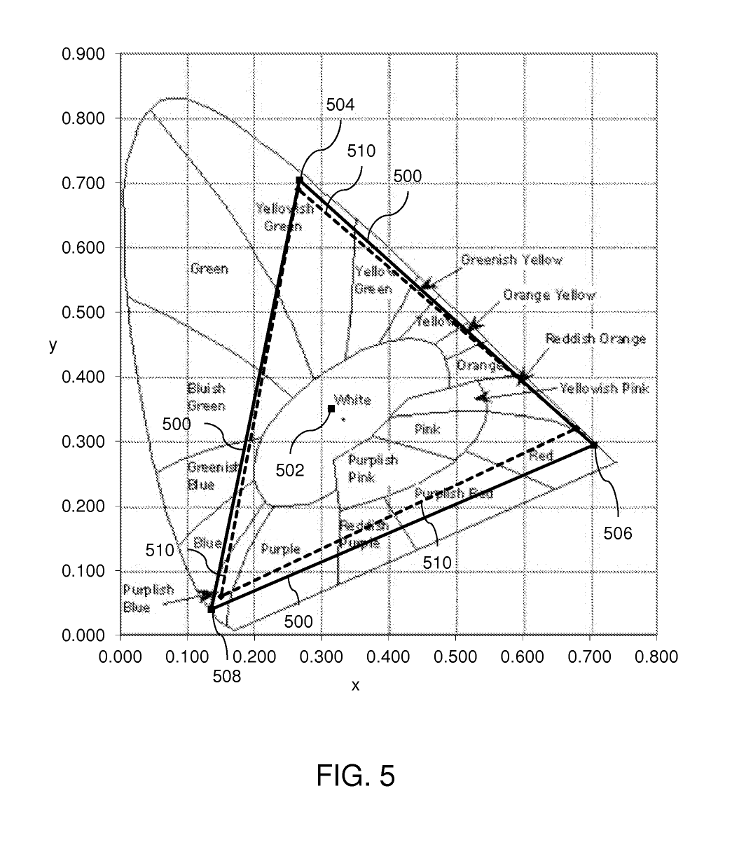

FIG. 5 shows a color chart of a laser projection system with a KGW crystal in a multipass cell. The x and y axes represent the x and y coordinates of the Commission Internationale de L'Eclairage (CIE) 1931 color space. First triangle 500 (solid line) shows the color gamut that results from the laser spectrum of FIG. 4. The red primary color is shown by first point 506. The green primary color is shown by second point 504. The blue primary color is shown by third point 508. The white color is shown by fourth point 502. Second triangle 510 (dashed line) shows the DCI standard color gamut that is required for cinema applications. Because first triangle 500 includes the entire area of second triangle 510, the laser system can meet the requirements of the DCI color space. Fourth point 502 meets the requirements of the DCI standard white point.

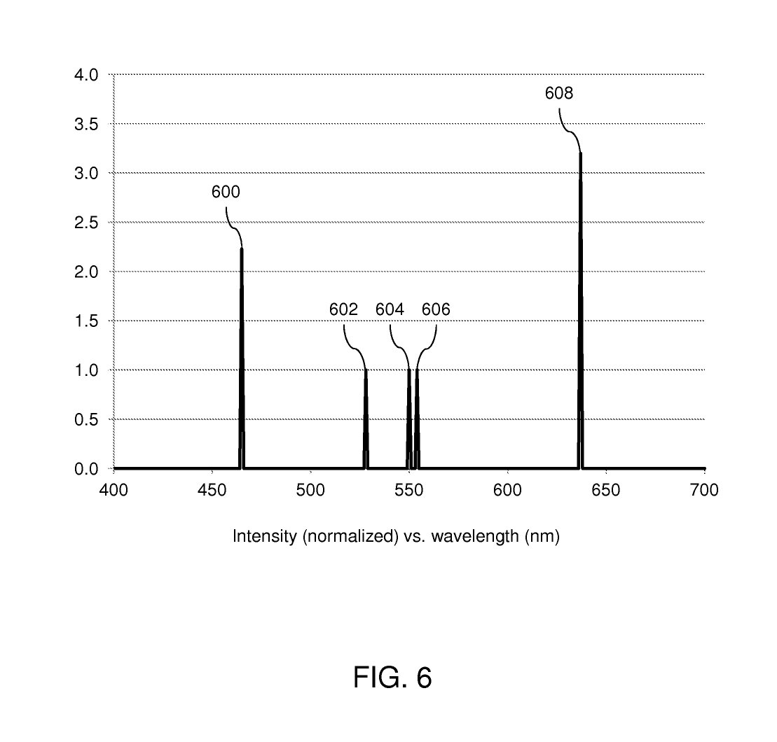

FIG. 6 shows a spectral graph of a laser projection system with a KGW crystal in a resonant cavity. The horizontal axis represents wavelength in nanometers and the vertical axis represents normalized light intensity. First peak 600 is generated by blue laser diodes at 465 nm. Second peak 602, third peak 604, and fourth peak 606 correspond to the spectral output of the laser projection systems shown in FIG. 2 and FIG. 3. Second peak 602 is formed from unshifted green light at 528 nm. Third peak 604 and fourth peak 606 are formed from SRS light at 550 nm and 554 nm. Fifth peak 608 is generated by red laser diodes at 637 nm. Second peak 602, third peak 604, and fourth peak 606 represent a despeckled green primary color. The vertical axis is normalized to second peak 602. Although not shown to scale in FIG. 6, second peak 602 is typically a very narrow peak that has a width of much less than one nanometer, whereas the other peaks typically have bandwidths in the range of 1 to 5 nm each. Third peak 604 and fourth peak 606 are broadened by the SRS process. First peak 600 and fifth peak 608 are broadened by the properties of the laser diodes that are used to create those peaks. The amplitudes of third peak 604 and fourth peak 606 are determined by the KGW conversion parameters such as the beam diameter and length in the KGW crystal and the green laser peak power and pulse shape. The amplitudes of first peak 600, second peak 602, and fifth peak 608 are determined by the output powers of the blue, green, and red lasers respectively.

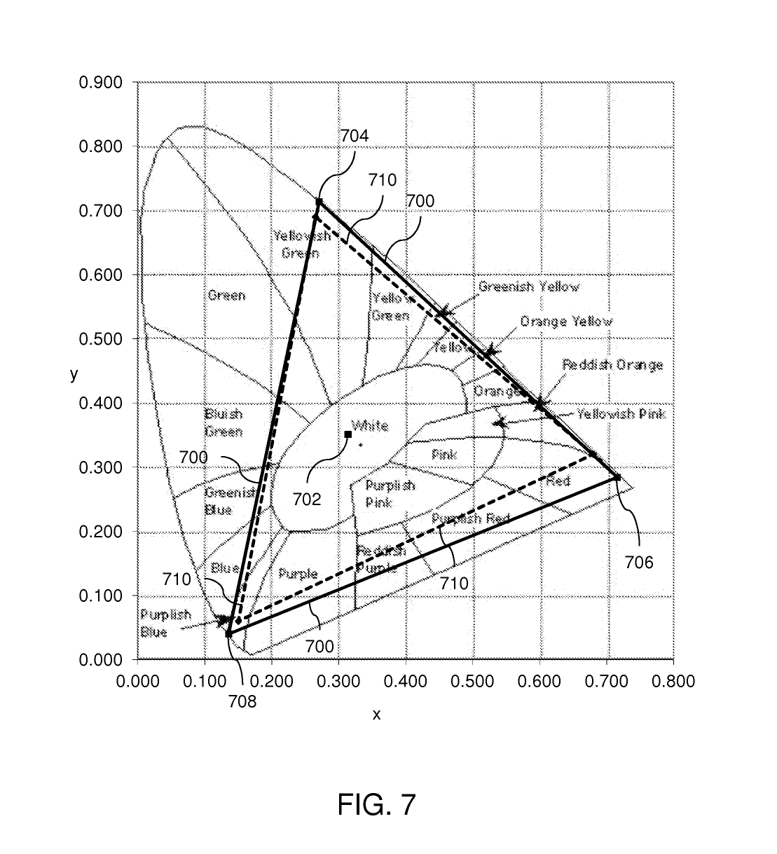

FIG. 7 shows a color chart of a laser projection system with a KGW crystal in a resonant cavity. The x and y axes represent the x and y coordinates of the CIE 1931 color space. First triangle 700 (solid line) shows the color gamut that results from the laser spectrum of FIG. 6. The red primary color is shown by first point 706. The green primary color is shown by second point 704. The blue primary color is shown by third point 708. The white color is shown by fourth point 702. Second triangle 710 (dashed line) shows the DCI standard color gamut that is required for cinema applications. Because first triangle 700 includes the entire area of second triangle 710, the laser system can meet the requirements of the DCI color space. Fourth point 702 meets the requirements of the DCI standard white point.

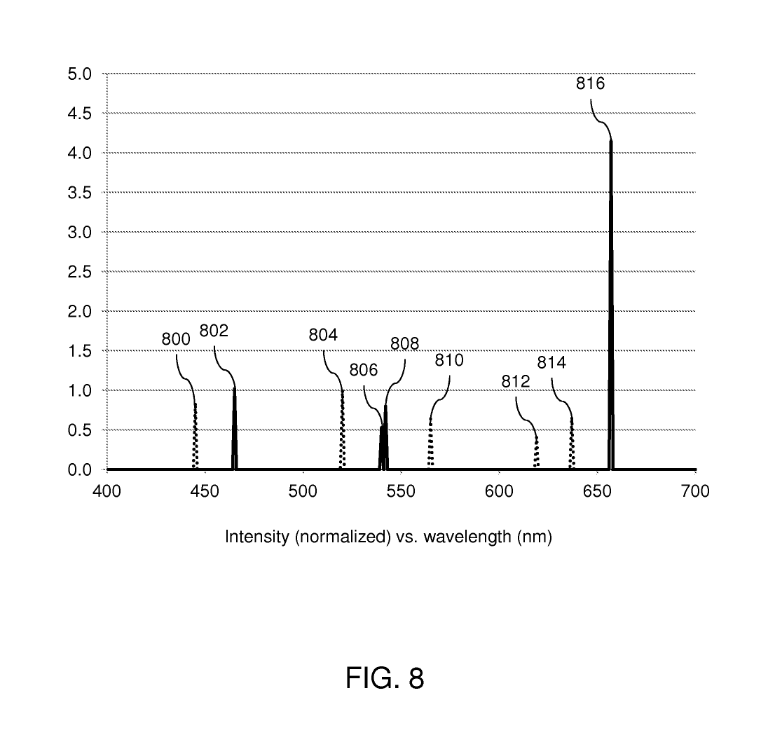

FIG. 8 shows a spectral graph of a stereoscopic laser projection system with a KGW crystal in a multipass cell. The horizontal axis represents wavelength in nanometers and the vertical axis represents normalized light intensity. First peak 800 is generated by blue laser diodes at 445 nm. Second peak 802 is generated by blue laser diodes at 465 nm. Third peak 804, fifth peak 808, sixth peak 810, and seventh peak 812 correspond to the spectral output of the laser projection system shown in FIG. 1. Third peak 804 is formed from unshifted green light at 520 nm. Fifth peak 808, sixth peak 810, and seventh peak 812 are formed from SRS light at 542 nm, 565 nm, and 619 nm. Fourth peak 806 at 540 nm is generated by a separate green laser. Eighth peak 814 is generated by red laser diodes at 637 nm. Ninth peak 816 is generated by red laser diodes at 657 nm. First peak 800, third peak 804, sixth peak 810, seventh peak 812, and eighth peak 814 (dotted line) represent primary colors for one eye of a stereoscopic image. Second peak 802, fourth peak 806, fifth peak 808, and ninth peak 816 (solid line) represent primary colors for the other eye of the stereoscopic image. Third peak 804 and third peak 810 represent a despeckled green primary color for one eye of the stereoscopic image. Fourth peak 806 and fifth peak 808 represent a despeckled green primary color for the other eye of the stereoscopic image. Seventh peak 812 and eighth peak 814 represent a despeckled red primary color for one eye of the stereoscopic image. An SRS peak at 591 nm is not shown because it is filtered out by low projector transmission between the green and red bands. The vertical axis is normalized to third peak 804. Although not shown to scale in FIG. 8, third peak 804 and fourth peak 806 are typically very narrow peaks that have a width of much less than one nanometer, whereas the other peaks typically have bandwidths in the range of 1 to 5 nm each. Fifth peak 808, sixth peak 810, and seventh peak 812 are broadened by the SRS process. First peak 800, second peak 802, eighth peak 814, and ninth peak 816 are broadened by the properties of the laser diodes that are used to create those peaks. The amplitudes of fifth peak 808, sixth peak 810, and seventh peak 812 are determined by the KGW conversion parameters such as the beam diameter and length in the KGW crystal and the green laser peak power and pulse shape. The amplitudes of first peak 800, second peak 802, third peak 804, fourth peak 806, eighth peak 814, and ninth peak 816 are determined by the output powers of the blue, green, and red lasers respectively.

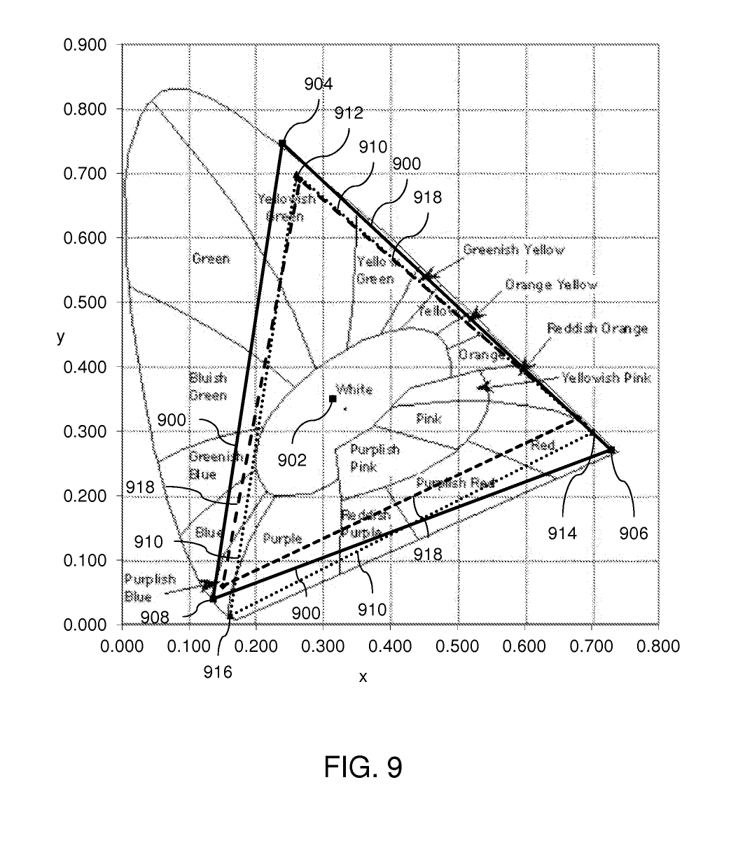

FIG. 9 is a color chart of a stereoscopic laser projection system with a KGW crystal in a multipass cell. The x and y axes represent the x and y coordinates of the CIE 1931 color space. First triangle 900 (solid line) shows the color gamut that results from second peak 802, fourth peak 806, fifth peak 808, and ninth peak 816 (solid line) laser spectrum of FIG. 8. The red primary color is shown by first point 906. The green primary color is shown by second point 904. The blue primary color is shown by third point 908. The white color for these peaks is shown by fourth point 902. Second triangle 910 (dotted line) shows the color gamut that results from first peak 800, third peak 804, sixth peak 810, seventh peak 812, and eighth peak 814 (dotted line) laser spectrum of FIG. 8. The red primary color is shown by fifth point 914. The green primary color is shown by sixth point 912. The blue primary color is shown by seventh point 916. The white color for these peaks is again shown by fourth point 902. Third triangle 918 (dashed line) shows the DCI standard color gamut that is required for cinema applications. Because first triangle 900 and second triangle 910 almost include the entire area of third triangle 918, the laser system is close to meeting the requirements of the DCI color space for each eye separately. When the two eyes are combined, the average will meet the DCI requirements better than each eye separately. Fourth point 902 meets the requirements of the DCI standard white point for each eye.

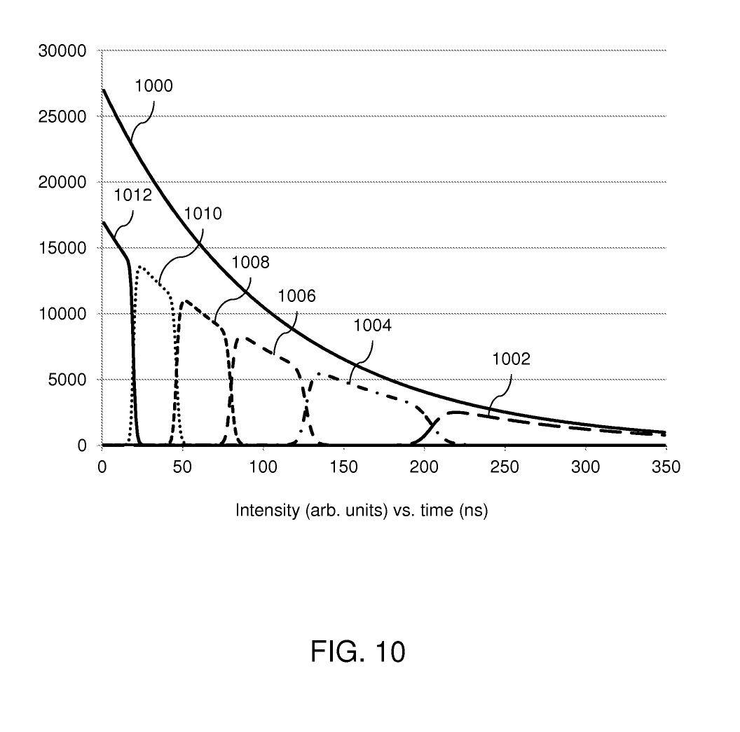

A computer model was utilized to calculate the conversion properties of a KGW crystal with a pulsed laser beam pump that creates Raman gain in the crystal to produce Stokes-shifted peaks of SRS light. The model utilizes several parameters of the crystal and laser source to determine the Stokes-shifted peaks. For the example shown in FIG. 10, the Stokes shift was 768 cm⁻¹, the Raman gain cross section was 1.4×10⁻⁹, the average laser spot size in the crystal was 250 micrometers in diameter, the laser pulse energy was 2×10⁻³ joules, the input pulse full-width half-maximum was 70 ns, the crystal physical length was 50 mm with 5 passes (total effective length of 250 mm), the spontaneous Raman seed power was 1×10⁻⁹ J, the quantum defect level was 0.95, and the crystal transmission was 99% over the total effective length. The input pulse to the KGW crystal was based on the output pulse from a green fiber laser that has a pulse shape with exponential decay. FIG. 10 shows a computer-simulated time graph of SRS in a KGW crystal. The x-axis represents time in nanosecond, and the y-axis represents intensity in arbitrary units. First curve 1000 shows the input pulse with exponential decay. Second curve 1002 shows the residual energy that is not Stokes shifted. Third curve 1004 shows the first Stokes-shifted peak. Fourth curve 1006 shows the second Stokes-shifted peak. Fifth curve 1008 shows the third Stokes-shifted peak. Sixth curve 1010 shows the fourth Stokes-shifted peak. Seventh curve 1012 shows the fifth Stokes-shifted peak. Overall, FIG. 10 describes the evolution in time of SRS process.

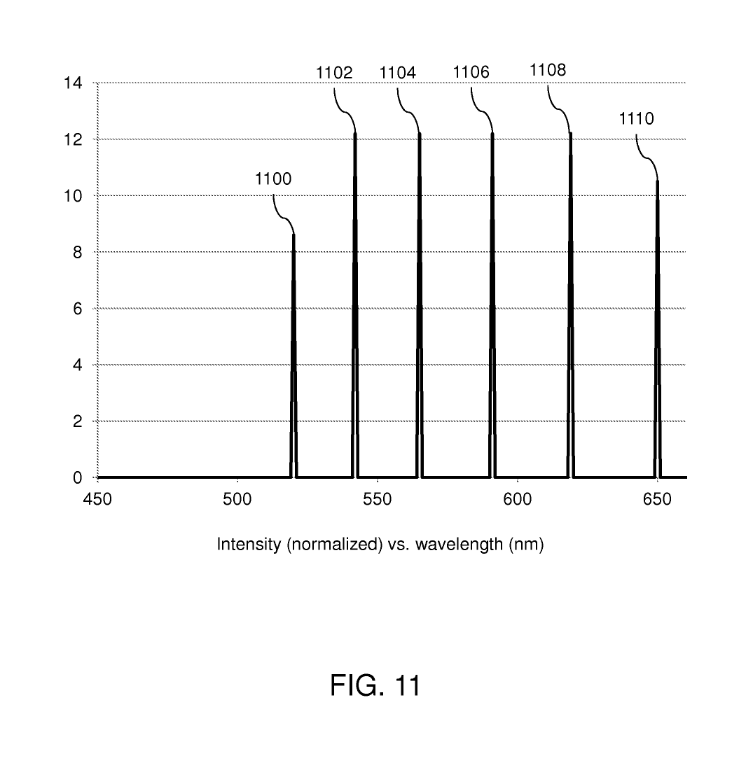

The model used to generate FIG. 10 was used with the same parameters to generate FIG. 11 which shows a spectral graph of SRS in a KGW crystal. First peak 1100 shows an unshifted peak used to pump the crystal at 520 nm. Second peak 1102 shows the first Stokes-shifted peak at 542 nm. Third peak 1104 shows the second Stokes-shifted peak at 565 nm. Fourth peak 1106 shows the third Stokes-shifted peak at 591 nm. Fifth peak 1108 shows the fourth Stokes-shifted peak at 619 nm. Sixth peak 1110 shows the fifth Stokes-shifted peak at 650 nm.

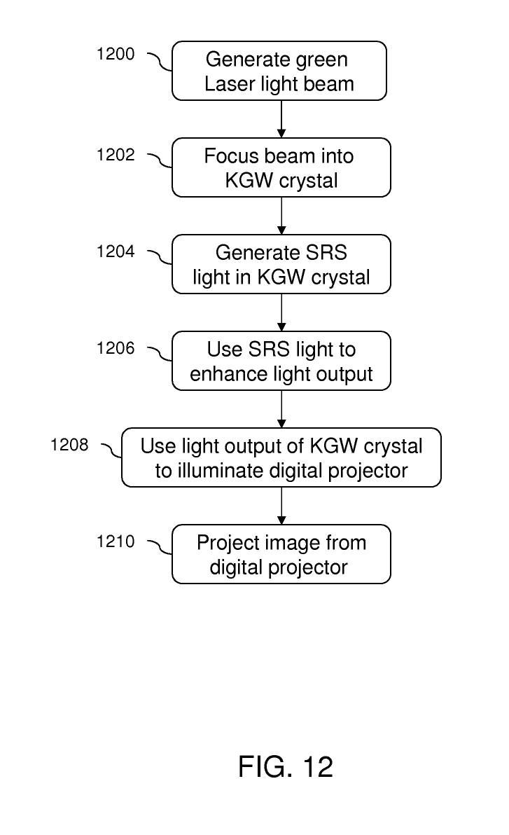

FIG. 12 shows a flowchart of a method of laser projection with a KGW crystal. In step 1200, a green laser light beam is generated. In step 1202, the green laser light beam is focused into a KGW crystal. In step 1204, SRS light is generated in the KGW crystal. In step 1206, the SRS light is used to enhance the light output from the KGW crystal. In step 1208, the light output of the KGW crystal is used to illuminate a digital projector. In step 1210, the digital projector is used to project an image.

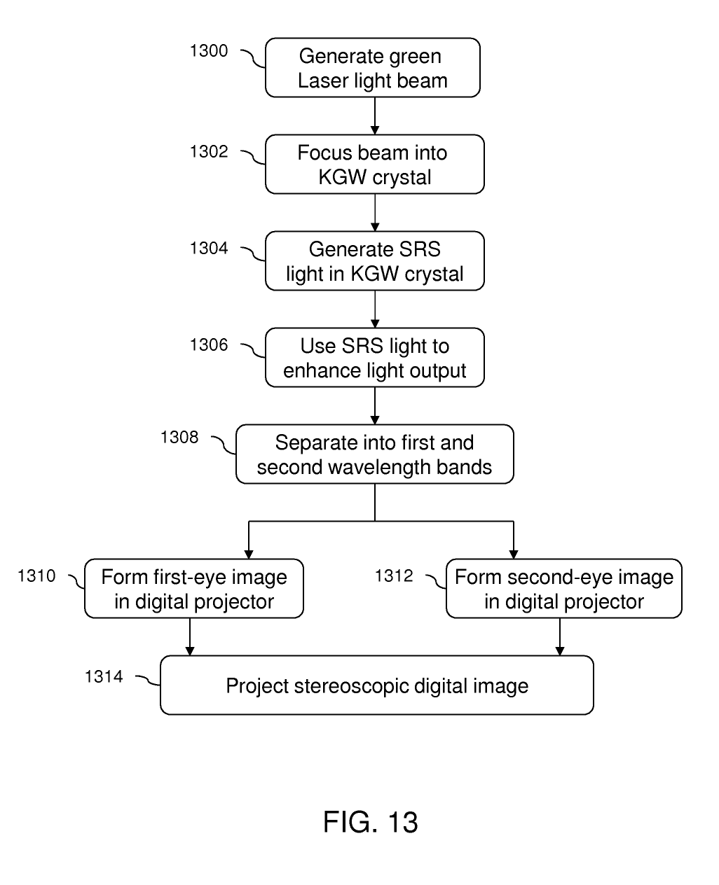

FIG. 13 shows a flowchart of a method of stereoscopic laser projection with a KGW crystal. In step 1300, a green laser light beam is generated. In step 1302, the green laser light beam is focused into a KGW crystal. In step 1304, SRS light is generated in the KGW crystal. In step 1306, the SRS light is used to enhance the light output from the KGW crystal. In step 1308, the light output from the KGW crystal is separated into first and second wavelength bands. In step 1310, the first wavelength band is used to form a first-eye image in a digital projector. In step 1312, the second wavelength band is used to form a second-eye image in a digital projector. In step 1314, the first-eye image and the second-eye image are used to project a stereoscopic image. Both stereoscopic images may be projected from a single digital projector or, alternately, each stereoscopic image may be projected from a separate digital projector.

In addition to the DCI color space shown in FIG. 5, FIG. 7, and FIG. 9, other target color spaces can be achieved with SRS light generated in a KGW crystal. One such color space is The International Telecommunication Union Radiocommunication (ITU-R) Recommendation 709 also known as Rec. 709.

The computer model utilized to calculate the results shown in FIG. 10 and FIG. 11 can be used to optimize the Stimulated Raman conversion process and transfer of power in the series of cascaded Raman shifts to longer wavelengths. This enables design of a system that efficiently converts power to higher-order Stokes peaks. It also enables the calculation of the spectral output behavior of the system. This can be utilized to provide a spectrum that is controlled to meet the requirements specific applications such as the DCI specification. This model is a simplification of the general problem of nonlinear processes in crystals. It does not account for four wave mixing effects for example. However the results of the model are in general agreement with experimentally determined results.

KGW is a biaxial crystal with Raman shifts that are dependent on polarization orientation. The Raman shift is either 768 cm⁻¹ or 901 cm⁻¹. The 768 cm⁻¹ shift is advantageous for despeckling because minimal peak spacing enables the maximum number of peaks to fit into the visible bands in order to achieve maximum despeckling. The crystal is typically cut to allow propagation along the b-axis. The output wavelength from the Raman crystal may be controlled by an optical waveplate that controls the polarization orientation of the pump laser beam.

As shown in FIG. 3, a green laser source may be constructed with multiple wavelength output in the green and red bands by utilizing a solid-state laser that includes a neodymium or ytterbium-doped crystal (such YAG, YVO₄ or YLF) to provide an IR laser beam at a wavelength of approximately one micron with multiple nonlinear processes occurring in the laser cavity. By placing a nonlinear conversion crystal in the laser cavity it is possible to utilize the high finesse of the IR laser cavity to efficiently convert IR radiation to visible green light. The laser cavity may include several mirrors with high reflectivity at a wavelength near one micron. The high finesse of the laser cavity increases the IR flux in the cavity to provide the intense beam needed for the nonlinear conversion processes. The laser cavity may have curved mirrors or lensing elements that control the laser mode size in the cavity. The laser mode may be shaped to provide a beam size that meets the nonlinear conversion conditions at the location of the nonlinear crystal to create green light. The nonlinear crystal may be constructed from a material such as LBO or potassium titanyl phosphate (KTP). A second nonlinear crystal constructed from a material such as KGW may be placed in the laser cavity such that the visible green light interacts with the KGW to produce additional SRS wavelengths of light in the green and red bands. The laser cavity may have mirrors and/or polarizers that control the green laser light in order to enable the SRS process in the KGW crystal. Specific wavelengths may be extracted from the cavity by a partially-reflective mirror. This mirror may let some or none of the shortest-wavelength visible light escape out of the laser cavity. Stokes-shifted light may be output from the laser cavity by the partially-reflective mirror. A polarization control technique utilizing one or more waveplates and a polarizer in the cavity may also be used to extract the Stokes-shifted wavelengths. The laser may be pumped or energized by a laser-diode assembly that pumps the laser crystal to an excited state which then creates the one micron laser radiation

Other implementations are also within the scope of the following claims.

What is claimed is:

1. An optical apparatus comprising:
a potassium gadolinium tungstate (KGW) crystal;
a green laser; and
a digital projector;
wherein the green laser illuminates the KGW crystal; a stimulated Raman scattering in the KGW crystal enhances an aspect of a light output from the KGW crystal; and the light output of the KGW crystal illuminates the digital projector.

2. The apparatus of claim 1 wherein the aspect of the light output from the KGW crystal is a speckle characteristic of the light output from the KGW crystal.

3. The apparatus of claim 1 wherein the light output from the KGW crystal comprises a band of green light and a band of red light.

4. The apparatus of claim 1 wherein the aspect of the light output from the KGW crystal is a color of the light output from the KGW crystal.

5. The apparatus of claim 1 further comprising:
a multipass cell;
wherein the green laser illuminates the KGW crystal with a plurality of passes that are determined by the multipass cell.

6. The apparatus of claim 1 further comprising:
a KGW resonant cavity;
wherein a resonant optical condition for the KGW crystal is determined by the KGW resonant cavity.

7. The apparatus of claim 1 wherein the green laser has a green laser resonant cavity and the KGW crystal is located inside the green laser resonant cavity.

8. The apparatus of claim 1 wherein a light output from the digital projector meets Digital Cinema Initiative color requirements.

9. The apparatus of claim 8 wherein the light output of the KGW crystal is separated into a first wavelength band and a second wavelength band; and the first wavelength band is used to form a first-eye image of a stereoscopic image projected from the digital projector; and the second wavelength band is used to form a second-eye image of the stereoscopic image.

10. The apparatus of claim 1 wherein the green laser comprises a fiber laser.

11. A method of despeckling comprising:
generating a green laser beam from a green laser;
focusing the laser beam into a potassium gadolinium tungstate (KGW) crystal;
generating stimulated Raman scattering light in the KGW crystal;
using the stimulated Raman scattering light to enhance an aspect of a light output from the KGW crystal; and
using the light output of the KGW crystal to illuminate a digital projector.

12. The method of claim 11 wherein the aspect of the light output from the KGW crystal is a speckle characteristic of the light output from the KGW crystal.

13. The method of claim 11 wherein the light output from the KGW crystal comprises a band of green light and a band of red light.

14. The method of claim 11 wherein the aspect of the light output from the KGW crystal is a color of the light output from the KGW crystal.

15. The method of claim 11 wherein the green laser beam illuminates the KGW crystal with a plurality of passes that are determined by a multipass cell.

16. The method of claim 11 wherein the green laser beam illuminates the KGW crystal with a resonant optical condition that is determined by a KGW resonant cavity.

17. The method of claim 11 wherein the green laser has a green laser resonant cavity and the KGW crystal is located inside the green laser resonant cavity.

18. The method of claim 11 wherein a light output from the digital projector meets Digital Cinema Initiative color requirements.

19. The method of claim 11 further comprising:
separating the light output of the KGW crystal into a first wavelength band and a second wavelength band;
using the first wavelength band to form a first-eye image of a stereoscopic image in the digital projector; and
projecting the stereoscopic image from the digital projector.

20. The method of claim 11 wherein the green laser comprises a fiber laser.
